(19) United States
(12) Patent Application Publication
(10) Pub. No.: US 2026/0033065 A1
(43) Pub. Date: Jan. 29, 2026

(54) METHOD OF MANUFACTURING LIGHT-EMITTING DEVICE, AND LIGHT-EMITTING DEVICE

(71) Applicant: Nichia Corporation, Anan-shi (JP)

(72) Inventor: Daisuke KASAI, Tokushima-shi (JP)

(73) Assignee: Nichia Corporation, Anan-shi (JP)

(21) Appl. No.: 19/276,733

(22) Filed: Jul. 22, 2025

(30) Foreign Application Priority Data
Jul. 29, 2024 (JP) 2024-122650

(51) Int. Cl. H10H 29/39; H10H 29/01

(52) U.S. Cl. CPC H10H 29/39; H10H 29/012

(57) ABSTRACT

A method of manufacturing a light-emitting device includes: preparing a light-emitting element; disposing a bonding member on an upper surface of the light-emitting element, the bonding member being uncured; disposing a light-transmissive member on an upper surface of the light-emitting element via the bonding member, and pressing the bonding member with the light-transmissive member to cause the bonding member to creep up along a lateral surface of the light-transmissive member; curing the bonding member; and removing a portion of the bonding member and a portion of the light-transmissive member, which comprises scraping the bonding member covering the lateral surface of the light-transmissive member, and the lateral surface of the light-transmissive member covered with the bonding member.

### CROSS REFERENCE TO RELATED APPLICATION

This application claims priority to Japanese Patent Applications No. 2024-122650, filed on Jul. 29, 2024, the entire contents of which are hereby incorporated by reference.

### BACKGROUND

The present disclosure relates to a method of manufacturing a light-emitting device, and a light-emitting device.

### BACKGROUND ART

There is a known light-emitting device including a substrate, a light-emitting element mounted on the substrate, a transparent material layer disposed on the light-emitting element, a plate-shaped optical layer mounted on the transparent material layer, and a reflective material layer disposed around the light-emitting element and the transparent material layer. In this light-emitting device, a lower surface of the plate-shaped optical layer is larger than an upper surface of the light-emitting element, and the reflective material layer forms an inclined surface connecting a lower end of a lateral surface of the light-emitting element and a lateral surface of the plate-shaped optical layer.

A method of manufacturing such a light-emitting device includes, for example, a first step of forming an uncured transparent material layer having an inclined lateral surface between the light-emitting element and the plate-shaped optical layer and then curing the transparent material layer, and a second step of forming a reflective material layer having an inclined lateral surface along the inclined lateral surface of the transparent material layer by filling a non-conductive reflective material around the transparent material layer and curing the non-conductive reflective material (for example, see Japanese Patent Publication No. 2012-004303).

### SUMMARY

An object of the present disclosure is to provide a method of manufacturing a light-emitting device that can improve luminance, and the light-emitting device.

A method of manufacturing a light-emitting device according to an embodiment of the present disclosure includes: preparing a light-emitting element; disposing a bonding member on an upper surface of the light-emitting element, the bonding member being uncured; disposing a light-transmissive member on an upper surface of the light-emitting element via the bonding member, and pressing the bonding member with the light-transmissive member to cause the bonding member to creep up along a lateral surface of the light-transmissive member; curing the bonding member; and scraping the bonding member covering the lateral surface of the light-transmissive member, and the lateral surface of the light-transmissive member covered with the bonding member, to remove a portion of the bonding member and a portion of the light-transmissive member.

A light-emitting device according to an embodiment of the present disclosure includes: a light-emitting element; a bonding member covering at least a portion of a lateral surface and an upper surface of the light-emitting element; a light-transmissive member disposed on the upper surface of the light-emitting element via the bonding member; a first covering member covering a lower surface of the light-emitting element, the first covering member being in contact with the bonding member; and a second covering member covering a lateral surface of the light-transmissive member and a lateral surface of the bonding member such that an upper surface of the light-transmissive member is exposed from the second covering member, the second covering member being in contact with the first covering member. The lateral surface of the light-transmissive member and the lateral surface of the bonding member are at least partially flush with each other.

According to an embodiment of the present disclosure, it is possible to provide a method of manufacturing a light-emitting device that can improve luminance, and the light-emitting device.

### BRIEF DESCRIPTION OF DRAWINGS

FIG. 1 is a schematic perspective view illustrating a light-emitting device according to the present embodiment.

FIG. 2 is a schematic cross-sectional view taken along line II-II in FIG. 1.

FIG. 3A is a schematic cross-sectional view illustrating an example of a manufacturing process of the light-emitting device according to the present embodiment.

FIG. 3B is a schematic cross-sectional view illustrating an example of the manufacturing process of the light-emitting device according to the present embodiment.

FIG. 3C is a schematic view of a wiring substrate as viewed from the upper surface side of the wiring substrate.

FIG. 3D is a schematic cross-sectional view illustrating an example of the manufacturing process of the light-emitting device according to the present embodiment.

FIG. 3E is a schematic cross-sectional view illustrating an example of the manufacturing process of the light-emitting device according to the present embodiment.

FIG. 3F is a schematic cross-sectional view illustrating an example of the manufacturing process of the light-emitting device according to the present embodiment.

FIG. 3G is a schematic view of the light-emitting element, a bonding member, and a light-transmissive member as viewed from the lower surface side of the light-emitting element.

FIG. 3H is a schematic cross-sectional view illustrating an example of the manufacturing process of the light-emitting device according to the present embodiment.

FIG. 3I is a schematic cross-sectional view illustrating an example of the manufacturing process of the light-emitting device according to the present embodiment.

FIG. 3J is a schematic cross-sectional view illustrating an example of the manufacturing process of the light-emitting device according to the present embodiment.

FIG. 3K is a schematic view of the light-emitting element, the bonding member, and the light-transmissive member as viewed from the lower surface side of the light-emitting element.

FIG. 3L is a schematic cross-sectional view illustrating an example of the manufacturing process of the light-emitting device according to the present embodiment.

FIG. 4 is a schematic cross-sectional view illustrating a light-emitting device according to Modified Example 1 of the present embodiment.

FIG. 5A is a schematic cross-sectional view illustrating an example of a manufacturing process of the light-emitting device according to Modified Example 1 of the present embodiment.

FIG. 5B is a schematic cross-sectional view illustrating an example of the manufacturing process of the light-emitting device according to Modified Example 1 of the present embodiment.

FIG. 5C is a schematic cross-sectional view illustrating an example of the manufacturing process of the light-emitting device according to Modified Example 1 of the present embodiment.

FIG. 5D is a schematic cross-sectional view illustrating an example of the manufacturing process of the light-emitting device according to Modified Example 1 of the present embodiment.

FIG. 6A is a schematic cross-sectional view illustrating another example of the manufacturing process of the light-emitting device according to Modified Example 1 of the present embodiment.

FIG. 6B is a schematic cross-sectional view illustrating another example of the manufacturing process of the light-emitting device according to Modified Example 1 of the present embodiment.

FIG. 6C is a schematic cross-sectional view illustrating another example of the manufacturing process of the light-emitting device according to Modified Example 1 of the present embodiment.

FIG. 7 is a schematic cross-sectional view illustrating a light-emitting device according to Modified Example 2 of the present embodiment.

### DETAILED DESCRIPTION

Hereinafter, a manufacturing method according to an embodiment of the present invention and a light-emitting device obtained by the manufacturing method (which hereinafter may be referred to as a “light-emitting device according to an embodiment”) will be described with reference to the drawings. In the following description, terms indicating a specific direction or position (for example, “upper,” “lower,” and other terms including those terms) are used as necessary. The use of those terms, however, is to facilitate understanding of the invention with reference to the drawings, and the technical scope of the present invention is not limited by the meanings of those terms. Parts having the same reference characters appearing in a plurality of drawings indicate identical or equivalent parts or members.

Further, the following embodiments exemplify a light-emitting device and the like for embodying the technical ideas of the present invention, but the present invention is not limited to the described embodiments. The dimensions, materials, shapes, relative arrangements, and the like of constituent components described below are not intended to limit the scope of the present invention to those alone, but are intended to provide examples, unless otherwise specified. The contents described in one embodiment can be applied to any of the other embodiments and modified examples. The sizes, the positional relationships, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view. In addition, even in a case in which the size or shape of some members is changed by processing, or the size or shape of some members is changed by pressing, the same names as those before the change may still be used for their descriptions.

### Light-Emitting Device 1 According to Embodiment

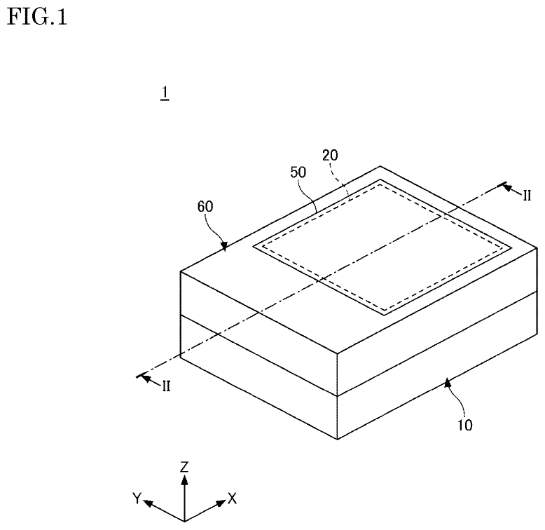

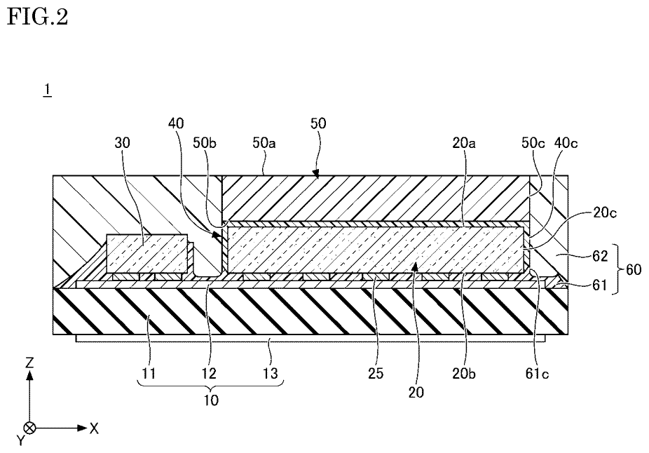

FIG. 1 is a schematic perspective view illustrating a light-emitting device according to the present embodiment. FIG. 2 is a cross-sectional view taken along line II-II in FIG. 1. FIG. 2 illustrates a cross section of a light-emitting device 1 taken along a plane perpendicular to an upper surface 20a of a light-emitting element 20. The same applies to the following cross-sectional views.

As illustrated in FIGS. 1 and 2, the light-emitting device 1 includes a wiring substrate 10, the light-emitting element 20, a protective element 30, a bonding member 40, a light-transmissive member 50, and a covering member 60. The light-emitting device 1 does not necessarily include the protective element 30 or the wiring substrate 10.

In the light-emitting device 1, the light-emitting element 20 is disposed on the wiring substrate 10. Furthermore, in the light-emitting device 1, the protective element 30 may be disposed on the wiring substrate 10. The light-emitting element 20 has the upper surface 20a, a plurality of lateral surfaces 20c connected with the upper surface 20a, and a lower surface 20b opposite to the upper surface 20a. The plurality of lateral surfaces 20c are connected with the upper surface 20a and the lower surface 20b. In other words, each of the plurality of lateral surfaces 20c has an outer edge connected with an outer edge of the upper surface 20a and an outer edge of the lower surface 20b. The light-emitting element 20 can emit light from the upper surface 20a, the lower surface 20b, and the lateral surfaces 20c.

The light-emitting element 20 has a substantially rectangular upper surface 20a. For example, the light-emitting element 20 has a substantially rectangular parallelepiped or substantially cubic external shape. In this case, the upper surface 20a and the lower surface 20b of the light-emitting element 20 are substantially rectangular, and the light-emitting element 20 has four substantially rectangular lateral surfaces 20c. The upper surface 20a of the light-emitting element 20 may have a polygonal shape such as a triangular shape or a hexagonal shape. Further, the light-emitting element 20 may have an external shape of a columnar body or a frustum body having a polygonal upper surface.

The bonding member 40 covers the upper surface 20a and at least a portion of the lateral surfaces 20c of the light-emitting element 20. To be more specific, the bonding member 40 covers the entirety of the upper surface 20a of the light-emitting element 20, and at least a portion of each of the lateral surfaces 20c at the upper end side (that is, the outer edge side connected with the upper surface 20a) thereof. The bonding member 40 includes a lateral surface 40c connected with the lateral surface 20c of the light-emitting element 20 and a lower surface 50b of the light-transmissive member 50. The bonding member 40 preferably covers a larger area of each of the lateral surfaces 20c of the light-emitting element 20, and more preferably covers substantially an entirety of each of the lateral surfaces 20c. That is, the lateral surface 40c of the bonding member 40 is preferably in contact with each of the lateral surfaces 20c of the light-emitting element 20 at a position close to the lower end side of the lateral surface 20c (i.e., the side connected with the lower surface 20b), and more preferably in contact with the lower end of each of the lateral surfaces 20c. To be more specific, the bonding member 40 covers preferably 75% or more and 100% or less, more preferably 90% or more and 100% or less of the region of each of the lateral surfaces 20c of the light-emitting element 20 in the height direction from the upper end side.

The light-transmissive member 50 is disposed on the upper surface 20a of the light-emitting element 20 via the bonding member 40. The light-transmissive member 50 has an upper surface 50a, a lower surface 50b on a side opposite to the upper surface 50a, and lateral surfaces 50c between the upper surface 50a and the lower surface 50b. The upper surface 50a of the light-transmissive member 50 serves as the main light-emitting surface of the light-emitting device 1 and constitutes the upper surface of the light-emitting device 1. The light-transmissive member 50 is disposed on the light-emitting element 20 such that the lower surface 50b of the light-transmissive member 50 faces the upper surface 20a of the light-emitting element 20 via the bonding member 40 disposed on the upper surface 20a of the light-emitting element 20. The light-transmissive member 50 is disposed such that the lower surface 50b of the light-transmissive member 50 is substantially parallel to the upper surface 20a of the light-emitting element 20. The shape of the lower surface 50b of the light-transmissive member is preferably similar to the shape of the upper surface 20a of the light-emitting element. For example, when the upper surface 20a of the light-emitting element has a rectangular shape, preferably the lower surface 50b of the light-transmissive member also has a rectangular shape.

The lower surface 50b of the light-transmissive member 50 is a flat surface. The upper surface 50a of the light-transmissive member 50 may be a flat surface parallel to the lower surface 50b, or a part or an entirety of the upper surface 50a may include a surface that is not parallel to the lower surface 50b. The lower surface 50b of the light-transmissive member 50 preferably has the same area as the upper surface 20a of the light-emitting element 20, or has an area larger than the upper surface 20a of the light-emitting element 20. The light-transmissive member 50 is preferably disposed such that the lower surface 50b of the light-transmissive member 50 encloses the light-emitting element 20 in a top view. In the light-emitting device 1, the bonding member 40 disposed between the lower surface 50b of the light-transmissive member 50 and the upper surface 20a of the light-emitting element 20 preferably covers a portion of the lower surface 50b of the light-transmissive member 50 that does not overlap the upper surface 20a of the light-emitting element 20 in a top view. Furthermore, in the light-emitting device 1, the bonding member 40 is preferably disposed to reach the outer edge of the lower surface 50b of the light-transmissive member 50, and more preferably, the entire lower surface 50b is covered with the bonding member 40. This allows a larger amount of light emitted from the light-emitting element 20 to enter the lower surface 50b of the light-transmissive member 50 through the bonding member 40.

The lateral surface 50c of the light-transmissive member 50 is a surface perpendicular to the upper surface 50a and/or the lower surface 50b. Here, the term “perpendicular” includes a case of being inclined at an angle within 90±5 degrees. The lateral surface 50c of the light-transmissive member 50 and the lateral surface 40c of the bonding member 40 are at least partially flush with each other. The lateral surface 50c of the light-transmissive member 50 and the lateral surface 40c of the bonding member 40 may be entirely flush with each other. Here, the expression “one surface and another surface being flush with each other” includes a case in which one surface is inclined at an angle within ±5 degrees relative to another surface. In addition, this expression includes a case in which there is a step within ±5 m at a boundary between one surface and another surface.

In order to improve the luminance of the light-emitting device 1, the light-emitting surface of the light-emitting device 1 preferably has a smaller area. In order to allow a larger amount of light emitted from the light-emitting element 20 to enter the light-transmissive member 50, the widths of the lower surface 50b of the light-transmissive member 50 in the X direction and the Y direction are preferably in a range of ±10% of the widths of the upper surface 20a of the light-emitting element 20 in the X direction and the Y direction. More preferably, the widths of the lower surface 50b of the light-transmissive member 50 in the X direction and the Y direction are substantially the same as the widths of the upper surface 20a of the light-emitting element 20 in the X direction and the Y direction. As used herein, the expression “substantially the same width” includes a case in which the widths of the light-transmissive member 50 in the X direction and the Y direction are within a range of +6% of the widths of the light-emitting element 20 in the X direction and the Y direction. For example, in the cross-sectional view of FIG. 2, when the width of the upper surface 20a of the light-emitting element 20 in the X direction is 1, the width of the lower surface 50b of the light-transmissive member 50 in the X direction is more than 1 and about 1.06 or less. Therefore, the width of the bonding member 40 covering the lateral surface 20c of the light-emitting element 20 in the X direction is approximately greater than 0 and less than or equal to 0.03. Similarly, when the width of the upper surface 20a of the light-emitting element 20 in the Y direction is 1, the width of the lower surface 50b of the light-transmissive member 50 in the Y direction is more than 1 and about 1.06 or less. Therefore, the width of the bonding member 40 covering the lateral surface 20c of the light-emitting element 20 in the Y direction is approximately greater than 0 and less than or equal to 0.03.

The covering member 60 allows the upper surface 50a of the light-transmissive member 50 to be exposed from it, and covers the lateral surfaces 40c of the bonding member 40 and the lateral surfaces 50c of the light-transmissive member 50. The covering member 60 further covers an upper surface of the wiring substrate 10. In the case in which the light-emitting device 1 includes the protective element 30, the covering member 60 preferably covers an upper surface and lateral surfaces of the protective element 30. The covering member 60 may cover the lower surface 20b of the light-emitting element 20. In the case in which a portion of the lateral surfaces 20c of the light-emitting element 20 is exposed from the bonding member 40, the covering member 60 may directly cover the portion of the lateral surfaces 20c of the light-emitting element 20 exposed from the bonding member 40.

The covering member 60 preferably has a light shielding property, and specifically has a light reflecting property and/or a light absorbing property. In particular, a material that can reflect light emitted from the light-emitting element 20 is preferably contained in the covering member 60.

With the covering member 60 covering the lateral surfaces 40c of the bonding member 40, light emitted from the lateral surfaces 20c of the light-emitting element 20 and transmitted through the bonding member 40 is reflected by the covering member 60. The covering member 60 may cover the lower surface 20b of the light-emitting element 20. In this case, light emitted from the lower surface 20b of the light-emitting element 20 and traveling downward can be reflected by the covering member 60. Thus, light extraction efficiency in the light-emitting device 1 can be improved.

The covering member 60 may be made up of a single portion or a plurality of portions. In the example illustrated in FIG. 2, the covering member 60 is made up of a plurality of portions including a first covering member 61 and a second covering member 62.

In the covering member 60, the first covering member 61 is disposed on the wiring substrate 10 side. The first covering member 61 covers, for example, the upper surface of the wiring substrate 10. The first covering member 61 is in contact with the bonding member 40. The first covering member 61 may cover the lower surface 20b of the light-emitting element 20. In the case in which the light-emitting device 1 includes the protective element 30, the first covering member 61 covers, for example, at least a portion of the lateral surfaces of the protective element 30. The first covering member 61 may cover the lower surface of the protective element 30.

The first covering member 61 includes a lateral surface 61c. The first covering member 61 is disposed on the wiring substrate 10 along the surfaces of the light-emitting element 20 and the protective element 30, and thus has an unspecified shape. In the example herein, a surface that is in contact with the lateral surface 40c of the bonding member 40 and extends toward the wiring substrate 10 is defined as the lateral surface 61c of the first covering member 61. The lateral surface 61c of the first covering member 61 may include a region that is flush with a lateral surface 50c of the light-transmissive member 50 and a lateral surface 40c of the bonding member 40.

In the covering member 60, the second covering member 62 is disposed on the first covering member 61, for example. The second covering member 62 allows the upper surface 50a of the light-transmissive member 50 to be exposed from it, covers the lateral surfaces 50c of the light-transmissive member 50 and the lateral surfaces 40c of the bonding member 40, and is in contact with the first covering member 61. In the case in which the light-emitting device 1 includes the protective element 30, the second covering member 62 covers, for example, the upper surface of the protective element 30. The second covering member 62 may cover a portion of the lateral surfaces of the protective element 30 exposed from the first covering member 61.

The lateral surface of the second covering member 62 constitutes the lateral surface of the light-emitting device 1 together with the lateral surface of the wiring substrate 10. The lateral surface of the second covering member 62 and the lateral surface of the wiring substrate 10 may be flush with each other, for example. The upper surface of the second covering member 62 and the upper surface 50a of the light-transmissive member 50 can be flush with each other, for example.

In the light-emitting device 1, when a current is supplied from an external power supply to the light-emitting element 20, the light-emitting element 20 emits light. Of the light emitted from the light-emitting element 20, the light traveling upward (i.e., toward the lower surface of the light-transmissive member) is extracted to the outside of the light-emitting device 1 through the bonding member 40 and the light-transmissive member 50. Of the light emitted from the light-emitting element 20, the light traveling downward is reflected by the covering member 60 and the wiring substrate 10, and extracted to the outside of the light-emitting device 1 through the light-emitting element 20, the bonding member 40, and the light-transmissive member 50. Of the light emitted from the light-emitting element 20, light traveling in the lateral direction is reflected at the interface between the lateral surface 20c of the bonding member 40 and the covering member 60 and extracted to the outside of the light-emitting device 1 through the bonding member 40 and the light-transmissive member 50.

In the light-emitting device 1, the lateral surface 50c of the light-transmissive member 50 and the lateral surface 40c of the bonding member 40 are connected and flush with each other. In the light-emitting device 1, the lateral surfaces 50c of the light-transmissive member 50 are not covered with the bonding member 40. This allows a larger amount of the light emitted from the light-emitting element 20 to enter the light-transmissive member 50 from the lower surface 50b of the light-transmissive member 50 via the bonding member 40. This can improve the luminance of the upper surface 50a of the light-transmissive member 50, which is the light-emitting surface of the light-emitting device 1.

In the light-emitting device 1, the widths of the light-transmissive member 50 in the X direction and the Y direction are substantially the same as the widths of the light-emitting element 20 in the X direction and the Y direction. That is, in the light-emitting device 1, the area of the upper surface 50a of the light-transmissive member 50, which is the main light-emitting surface, is substantially the same as the area of the upper surface 20a of the light-emitting element 20. Therefore, the area through which light emitted from the light-emitting element 20 and incident on the light-transmissive member 50 is guided is constant. That is, the optical path length of the light emitted from the light-emitting element 20 and radiated to the outside is shortened, and more light can be emitted from the upper surface 50a of the light-transmissive member 50. This increases the amount of light per unit area to be emitted from the upper surface 50a of the light-transmissive member 50, thereby allowing for increase in the luminance.

Hereinafter, elements constituting the light-emitting device 1 according to the embodiment will be described in detail.

### Wiring Substrate 10

The wiring substrate 10 is a member on which the light-emitting element 20 is disposed. The wiring substrate 10 includes a conductive member for supplying electric power to the light-emitting element from the outside, and a base body 11 supporting the conductive member. The wiring substrate 10 includes, for example, an upper surface conductive member 12 disposed at its upper surface on which the light-emitting element 20 is disposed, and a lower surface conductive member 13 disposed at its lower surface opposite to the upper surface. The base body 11 has, for example, a substantially rectangular parallelepiped shape or a substantially cubic shape. The base body 11 is preferably made of an insulating material that is less likely to transmit light emitted from the light-emitting element 20, external light, and the like. Examples of the material of the base body 11 include a single material selected from ceramics such as aluminum oxide, aluminum nitride, silicon nitride, and mullite, resins such as epoxy resin, silicone resin, modified epoxy resin, urethane resin, phenol resin, polyimide resin, BT resin, and polyphthalamide, semiconductors such as silicon, and metals such as copper and aluminum, and composite materials thereof. Among these, ceramic having good heat dissipation properties can be suitably used as the material of the base body 11.

The upper surface conductive member 12 includes a conductive member electrically connected to the light-emitting element 20 and a conductive member electrically connected to the protective element 30. The lower surface conductive member 13 includes an anode electrode and a cathode electrode having a region for establishing electrical connection with an external power supply (that is, serving as electrodes of the light-emitting device 1). For the upper surface conductive member 12 and the lower surface conductive member 13, for example, a metal such as iron, copper, nickel, aluminum, gold, silver, platinum, titanium, tungsten, or palladium, or an alloy containing at least one of these metals can be used. Further, the wiring substrate 10 may include an intermediate conductive member for connecting the upper surface conductive member 12 and the lower surface conductive member 13 inside and/or on the lateral surface of the base body 11.

The wiring substrate 10 may not include the lower surface conductive member 13. In this case, an anode electrode and a cathode electrode electrically connected to an external power supply may be disposed on the upper surface or the lateral surface of the wiring substrate 10.

The wiring substrate 10 may have a recess in the upper surface, and the light-emitting device 1 may have a structure in which the light-emitting element 20 is disposed at the bottom of the recess of the wiring substrate 10. The light-emitting device 1 may have a structure without the wiring substrate 10. For example, the light-emitting device may have a structure in which a metal member (e.g., electrode of the light-emitting element 20 described below) exposed from the covering member 60 covering the lower surface 20b of the light-emitting element 20 is provided as an electrode of the light-emitting device 1.

In the wiring substrate 10, a lead may be used as the conductive member. In this case, the wiring substrate 10 includes a lead as the conductive member, and a resin molded body as the base body to hold the lead. For the lead, the above-described metal, alloy, or the like processed into a predetermined shape by processing such as rolling, punching, extrusion, etching such as wet or dry etching, or a combination thereof can be used.

### Light-Emitting Element 20

As the light-emitting element 20, a semiconductor light-emitting element such as a light-emitting diode (LED) chip or a semiconductor laser (LD) chip can be suitably used. Any appropriate shape, size, and the like can be selected for the light-emitting element 20. The light-emitting element 20 has, for example, positive and negative electrodes at the lower surface 20b. The light-emitting element 20 is disposed on the wiring substrate 10. The light-emitting element 20 is, for example, flip-chip mounted on the wiring substrate 10 via a conductive bonding member 25 with the lower surface 20b facing the wiring substrate 10. As the conductive bonding member 25, for example, a known member such as eutectic solder, conductive paste, or bump can be used.

The light-emitting element 20 includes, for example, a semiconductor structure and a support substrate supporting the semiconductor structure. The semiconductor structure includes an n-side semiconductor layer, a p-side semiconductor layer, and an active layer located between the n-side semiconductor layer and the p-side semiconductor layer. The active layer may have a single quantum well (SQW) structure, or may have a multi quantum well (MQW) structure including a plurality of well layers. The semiconductor structure includes a plurality of semiconductor layers each made of a nitride semiconductor. The nitride semiconductor encompasses all semiconductors having compositions represented by a chemical formula of InₓAl_{y}Ga_{1-x-y}N (0≤x, 0≤y, and x+y≤1), where composition ratios x and y are varied within respective ranges. The light emission peak wavelength of the active layer can be selected as appropriate according to the purpose. The active layer is configured to emit visible light or ultraviolet light, for example.

In the light-emitting element 20 a single semiconductor structure may be provided on a single support substrate, or a plurality of semiconductor layered bodies may be provided on a single support substrate. In addition, a single semiconductor structure may have one light-emitting layer or a plurality of light-emitting layers. The structure of the semiconductor structure having a plurality of light-emitting layers may be a structure including a plurality of active layers between one n-side semiconductor layer and one p-side semiconductor layer, or may be a structure in which a structure sequentially including an n-side semiconductor layer, an active layer, and a p-side semiconductor layer is repeated a plurality of times.

The light-emitting element 20 includes an n-electrode connected to the n-side semiconductor layer and a p-electrode connected to the p-side semiconductor layer. The p-electrode and the n-electrode may be disposed on different surface sides of the semiconductor layered body, or may be disposed on the same surface side. In the example herein, the electrodes including the p-electrode and the n-electrode are disposed on the same surface side of the semiconductor structure, the side on which the electrodes are disposed constitutes the lower surface 20b of the light-emitting element 20, and a surface of the support substrate on a side opposite to the surface thereof on which the semiconductor structure is disposed constitutes the upper surface 20a of the light-emitting element 20. Examples of the support substrate include an insulating substrate of sapphire or spinel (MgAl₂O₄), and a nitride-based semiconductor substrate of gallium nitride. To extract light emitted from the active layer through the support substrate, it is preferable that a light-transmissive material is used for the support substrate. The light-emitting element 20 does not necessarily include the support substrate. In this case, the surface opposite to the surface on which the electrodes of the semiconductor structure are disposed constitutes the upper surface 20a of the light-emitting element 20.

### Protective Element 30

The light-emitting device 1 can include other electronic components such as the protective element 30 in addition to the light-emitting element 20. The protective element 30 is, for example, a Zener diode. The light-emitting device 1 does not necessarily include the protective element 30.

### Bonding Member 40

The bonding member 40 is disposed between the light-emitting element 20 and the light-transmissive member 50 and bonds the light-emitting element 20 and the light-transmissive member 50. The bonding member 40 is light-transmissive and guides light emitted from the light-emitting element 20 to the light-transmissive member 50. With the bonding member 40 covering the lateral surfaces 20c of the light-emitting element 20, light emitted from the lateral surfaces 20c of the light-emitting element 20 can be easily guided to the light-transmissive member 50, so that the light extraction efficiency of the light-emitting device 1 can be improved.

The bonding member 40 is disposed to cover the upper surface 20a and each of the lateral surfaces 20c of the light-emitting element 20. For example, a light-transmissive resin can be used as the bonding member 40. Examples of the light-transmissive resin include thermosetting resins such as an epoxy resin, a modified epoxy resin, a silicone resin, and a modified silicone resin. Among them, a silicone resin having high heat resistance is preferably used. In addition, as the bonding member 40, a silicon alcoholate such as polysilazane having better heat resistance may be used. The bonding member 40 may contain a light diffusing member or a phosphor to be described later.

### Light-Transmissive Member 50

The light-transmissive member 50 is disposed on the light-emitting element 20 and transmits light emitted from the light-emitting element 20 to the outside. The light-transmissive member 50 transmits 60% or more, preferably 70% or more, of light emitted from the light-emitting element 20 and/or light having been wavelength-converted from the light emitted from the light-emitting element 20 (e.g., light having wavelengths in a range of 320 nm to 850 nm). The light-transmissive member 50 may be made of, for example, an inorganic material such as glass, ceramic, or sapphire, or an organic material such as a resin or a hybrid resin containing one or more of a silicone resin, a modified silicone resin, an epoxy resin, a modified epoxy resin, an acrylic resin, a phenol resin, and a fluororesin. The light-transmissive member 50 may contain a phosphor adapted to convert the wavelength of at least a portion of incident light. Examples of the light-transmissive member 50 containing the phosphor include a sintered body of phosphor and a material in which phosphor powder is contained in the above-described material. The light-transmissive member 50 may be a member in which a phosphor layer such as a resin layer containing a phosphor or a glass layer containing a phosphor is disposed on a surface of a light-transmissive plate that is a molded body made of resin, glass, ceramic, or the like. The light-transmissive member 50 may contain a filler such as a light-diffusing member depending on the purpose. In the case in which the light-transmissive member 50 contains a filler such as a light-diffusing member, the light-transmissive member 50 may be made of a resin, glass, ceramic, or other inorganic material containing a filler, or may be a member in which a light-diffusing layer, such as a resin layer containing a filler such as a light-diffusing member or a glass layer containing a filler, is disposed on a surface of a light-transmissive plate that is a molded body of a resin, glass, ceramic, or the like.

As the phosphor, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), quantum dots having a perovskite structure (for example, (Cs,FA,MA)(Pb,Sn)(F,Cl,Br,I)₃, where FA and MA represent formamidinium and methylammonium, respectively), group II-VI quantum dots (for example, CdSe), group III-V quantum dots (for example, InP), quantum dots having a chalcopyrite structure (for example, (Ag,Cu)(In,Ga)(S,Se)₂), or the like can be used.

As the light diffusion member, those known in the art can be used. For example, titanium oxide, silicon oxide, aluminum oxide, or barium titanate can be used.

When a resin is used as a binder of the phosphor layer or the light diffusion layer, examples of the resin include thermosetting resins such as an epoxy resin, a modified epoxy resin, a silicone resin, and a modified silicone resin.

### Covering Member 60

The covering member 60 is a member that allows the upper surface 50a of the light-transmissive member 50 to be exposed from it, and covers the lateral surfaces 40c of the bonding member 40 and the lateral surfaces 50c of the light-transmissive member 50. The covering member 60 preferably has, for example, a reflectance of 60% or more, and more preferably has a reflectance of 70% or more, 80% or more, or 90% or more, of the light emitted from the light-emitting element 20.

Preferably, the covering member 60 is formed using an insulating material. The covering member 60 is, for example, a member containing particles of a light-reflective substance and a base material. Examples of the base material to be used for the covering member 60 include a resin or a hybrid resin containing one or more of a silicone resin, a modified silicone resin, an epoxy resin, a modified epoxy resin, a urea resin, an acrylic resin, a phenol resin, a bismaleimide triazine resin, and a polyphthalamide resin. Among these, it is particularly preferable to use a silicone resin, which has good light resistance, heat resistance, electrical insulation properties and flexibility. The base material may be made of an inorganic material such as an alkali metal silicate. Examples of the light-reflective substance include titanium oxide, silicon oxide, aluminum oxide, zirconium oxide, magnesium oxide, potassium titanate, barium titanate, zinc oxide, silicon nitride, aluminum nitride, boron nitride, calcium carbonate, calcium hydroxide, calcium silicate, and combinations thereof. Among these, considering light reflection, titanium oxide having a relatively high refractive index is preferably used.

As described above, the covering member 60 may be made up of the first covering member 61 and the second covering member 62. In this case, each of the first covering member 61 and the second covering member 62 can be made using a material selected from the materials described above as examples of the material of the covering member 60. When the covering member 60 is made up of the first covering member 61 and the second covering member 62, for example, the second covering member 62 constituting the outer surfaces of the light-emitting device 1 can be made of a material having a high mechanical strength while the first covering member 61 covering the lower surface 20b of the light-emitting element 20 is made of a material having a low elastic modulus and a low linear expansion coefficient, so that a stress due to resin expansion can be reduced.

### Method of Manufacturing Light-emitting Device According to Embodiment

A method of manufacturing a light-emitting device according to an embodiment includes: preparing a light-emitting element; disposing a bonding member on an upper surface of the light-emitting element, the bonding member being uncured; disposing a light-transmissive member on an upper surface of the light-emitting element via the bonding member, and pressing the bonding member with the light-transmissive member to cause the bonding member to creep up along a lateral surface of the light-transmissive member; curing the bonding member; and scraping the bonding member covering the lateral surface of the light-transmissive member and the lateral surface of the light-transmissive member covered with the bonding member, to remove a portion of the bonding member and a portion of the light-transmissive member.

The method of manufacturing a light-emitting device according to the present embodiment may further include disposing a first covering member covering at least a portion of the bonding member before the step of removing.

The method of manufacturing a light-emitting device according to the present embodiment may further include, after the step of removing, disposing a second covering member to cover the lateral surface of the light-transmissive member and a lateral surface of the bonding member such that an upper surface of the light-transmissive member is exposed from second covering member and.

Further, the method of manufacturing a light-emitting device according to the embodiment may include, before the step of disposing the bonding member, preparing a wiring substrate and disposing the light-emitting element on the wiring substrate.

Hereinafter, the manufacturing process of the method of manufacturing the light-emitting device according to the present embodiment will be described with reference to the drawings.

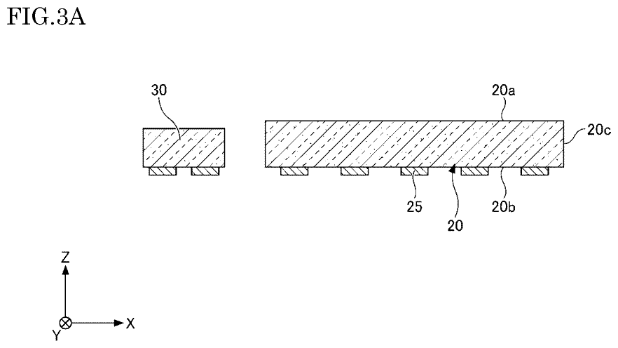

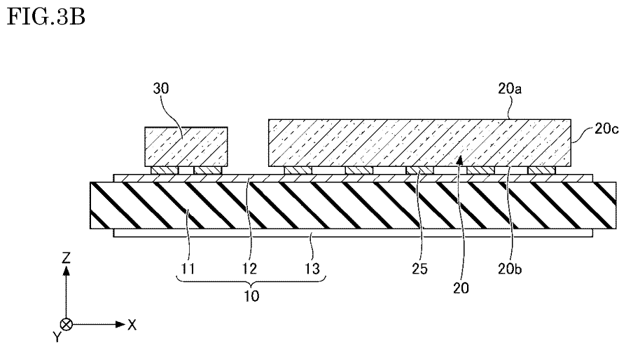

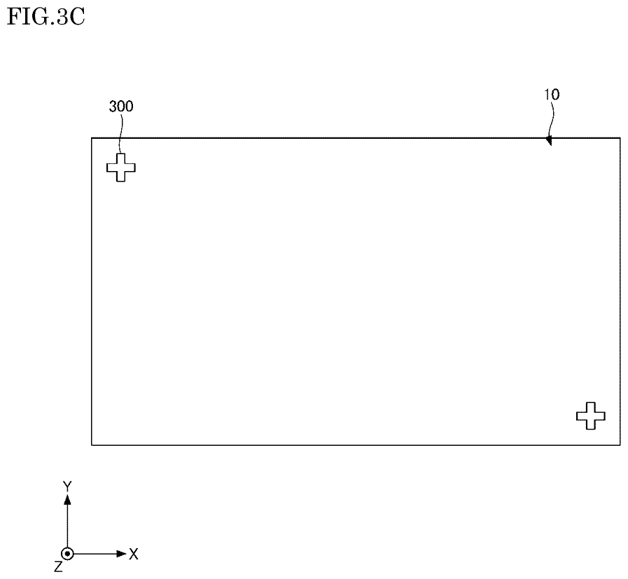

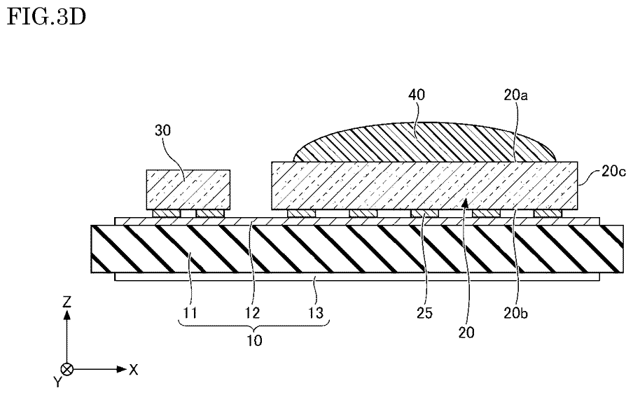

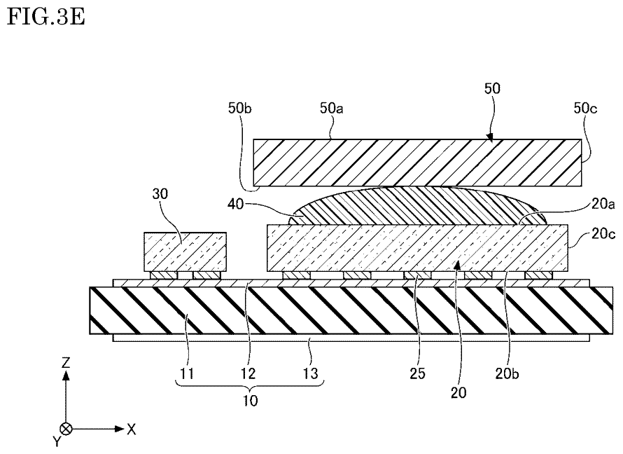

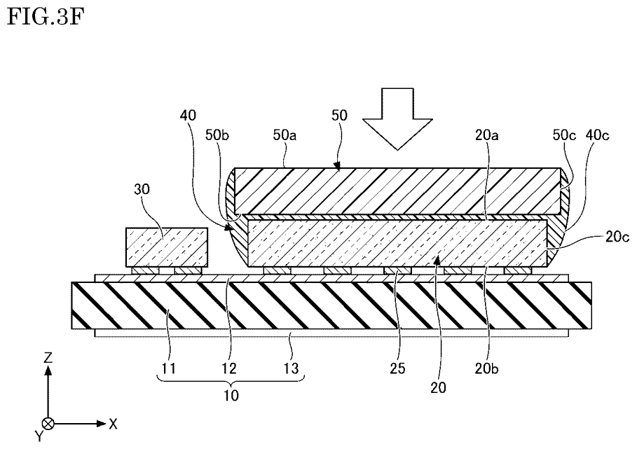

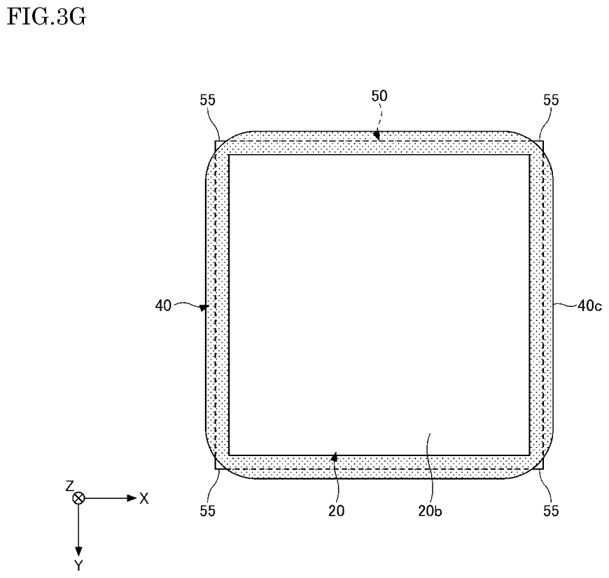

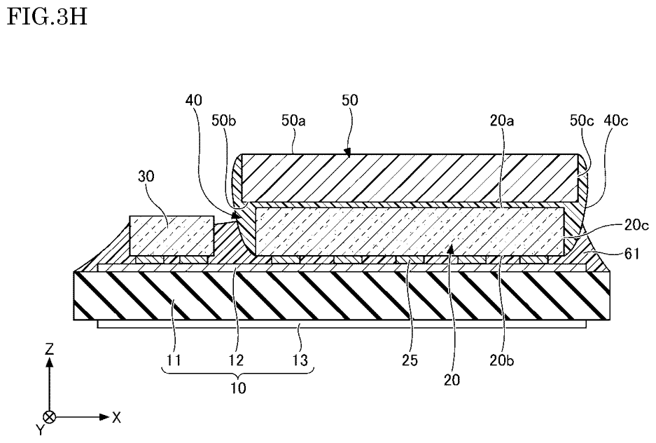

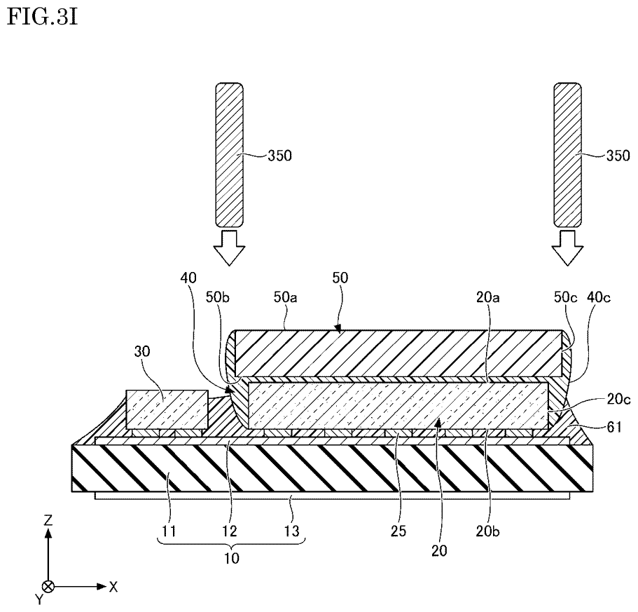

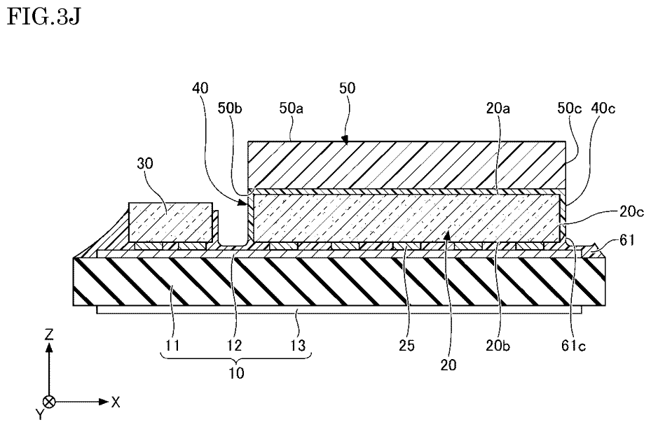

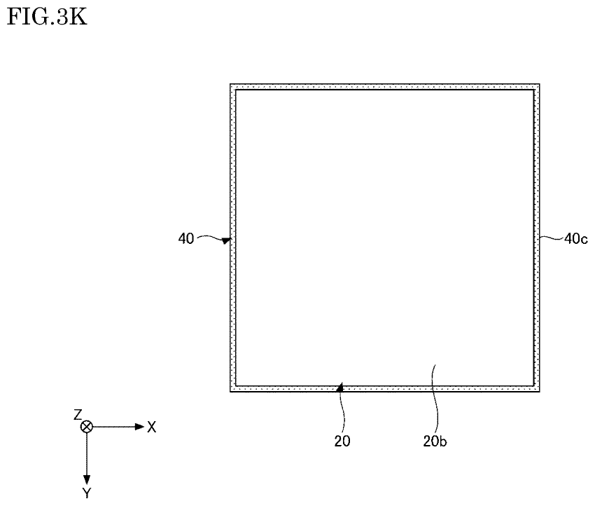

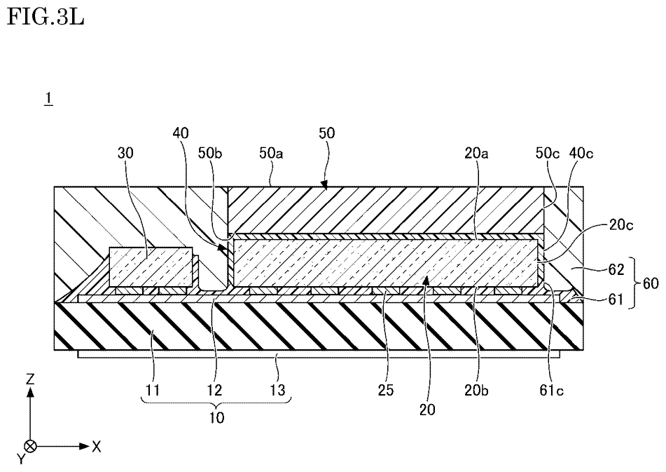

FIGS. 3A to 3L are diagrams schematically illustrating a manufacturing process of the light-emitting device according to the present embodiment. To be more specific, FIGS. 3A, 3B, 3D to 3F, 3H to 3J, and 3L are cross-sectional views schematically illustrating an example of the manufacturing process of the light-emitting device according to the present embodiment. FIG. 3C is a schematic view of the wiring substrate as viewed from the upper surface side of the wiring substrate. FIGS. 3G and 3K are views of the light-emitting element, the bonding member, and the light-transmissive member as viewed from the lower surface side of the light-emitting element. In FIG. 3C, the upper surface conductive member of the wiring substrate is not illustrated.

### Step of Preparing Light-Emitting Element

First, as illustrated in FIG. 3A, the light-emitting element 20 having the upper surface 20a, the lower surface 20b, and the plurality of lateral surfaces 20c connected with the upper surface 20a and the lower surface 20b is prepared. Further, the protective element 30 is prepared. The protective element 30 is prepared as necessary. The light-emitting element 20 can be prepared through some or all of a plurality of steps such as a step of forming a semiconductor layered body and a step of forming an electrode. In the description of the method manufacturing, the expression “preparing” a member is not limited to manufacturing the member, and encompasses acquiring the member such as purchasing the member or being handed over the member.

### Step of Providing Wiring Substrate and Step of Disposing Light-Emitting Element on Wiring Substrate

Next, as illustrated in FIG. 3B, the wiring substrate 10 is prepared, and the light-emitting element 20 is disposed on the wiring substrate 10. Specifically, first, the wiring substrate 10 including the base body 11, the upper surface conductive member 12 disposed on an upper surface of the base body 11, and the lower surface conductive member 13 disposed on a lower surface of the base body 11 is prepared. Then, the light-emitting element 20 is disposed on the upper surface side of the wiring substrate 10. In the example herein, the protective element 30 is disposed together with the light-emitting element 20. The light-emitting element 20 and the protective element 30 are, for example, flip-chip mounted on the wiring substrate 10 with the surfaces on which the respective electrodes are disposed facing the upper surface conductive member 12.

As illustrated in FIG. 3C, the wiring substrate 10 can include an alignment mark 300 to be used for alignment of the light-emitting element 20 in the region constituting an individual light-emitting device 1. The alignment mark 300 may be formed of, for example, a wiring pattern the same as or similar to that of the upper surface conductive member 12. The alignment mark 300 has, for example, a cross shape, and a plurality of alignment marks may be arranged in a diagonal direction of the wiring substrate 10. By using the alignment mark 300 as a reference, the light-emitting element 20 can be accurately disposed at a desired position on the wiring substrate 10. The alignment mark may be disposed within the region constituting the light-emitting device 1 or outside the region. Alternatively, a collective substrate including a plurality of regions to be singulated into the light-emitting device 1 may be prepared as the wiring substrate 10.

### Step of Disposing Uncured Bonding Member on Upper Surface of Light-Emitting Element

Next, as illustrated in FIG. 3D, an uncured bonding member 40 is disposed on the upper surface 20a of the light-emitting element 20. To be specific, first, a nozzle is disposed above the light-emitting element 20, and the uncured bonding member 40 is discharged from the nozzle toward the upper surface 20a of the light-emitting element 20. Then, after a predetermined amount of the bonding member 40 is discharged, the discharge is stopped, and the nozzle is moved from above the light-emitting element 20. The uncured bonding member 40 has a shape illustrated in FIG. 3D due to a surface tension. The term “uncured” refers to a state before the curing reaction proceeds, that is, a state before an operation for causing the curing reaction to proceed is performed. Examples of the operation for causing the curing reaction to proceed include heating and light irradiation. The curing reaction may slightly proceed before the operation for causing the curing reaction to proceed, and the uncured state also includes such a state. To be more specific, it is sufficient that the bonding member 40 has at least fluidity that allows the bonding member 40 to creep up in FIG. 3F described later.

### Step of Disposing Light-Transmissive Member on Upper Surface of Light-Emitting Element Via Bonding Member and Curing Bonding Member

Next, as illustrated in FIG. 3E, the light-transmissive member 50 is prepared, and the light-transmissive member 50 is disposed on the upper surface 20a of the light-emitting element 20 via the uncured bonding member 40. The areas of the upper surface 50a and the lower surface 50b of the light-transmissive member 50 to be prepared are larger than those of the light-transmissive member 50 to be mounted on the light-emitting device 1.

Next, as illustrated in FIG. 3F, the bonding member 40 is pressed by the light-transmissive member 50 in the direction indicated by the arrow to allow the bonding member 40 to creep up along the lateral surfaces 50c of the light-transmissive member 50. The shape of the bonding member 40 is changed by pressing, and the bonding member 40 is disposed with a substantially constant thickness between the upper surface 20a of the light-emitting element 20 and the lower surface 50b of the light-transmissive member 50. Furthermore, the bonding member 40 spreads outward from the upper surface 20a of the light-emitting element 20 to cover a part or all of the lateral surfaces 20c of the light-emitting element 20, and creeps up along the lateral surfaces 50c of the light-transmissive member 50 to cover a part or all of the lateral surfaces 50c of the light-transmissive member 50. Thereafter, the bonding member 40 is cured. Thus, the light-transmissive member 50 and the light-emitting element 20 are bonded to each other via the bonding member 40. The curing can be performed by a known method such as heating in an oven.

The bonding member 40 is preferably spaced apart from the wiring substrate 10. With the bonding member 40 separated from the wiring substrate 10, the bonding member 40 can be inhibited from having an irregular shape and thus light from the light-emitting element 20 is less likely to be reflected in an unintended direction, so that the light extraction efficiency of the light-emitting device 1 can be improved.

By pressing the bonding member 40 with the light-transmissive member 50 to cause the bonding member 40 to flow, the bonding member 40 can be disposed on the lower surface 50b of the light-transmissive member 50 that does not face the upper surface 20a of the light-emitting element. The bonding member 40 covers a part or an entirety of the lower surface 50b of the light-transmissive member 50. As an example in which the bonding member 40 covers a portion of the lower surface 50b of the light-transmissive member 50, as illustrated in FIG. 3G, there may be a case in which corner portions 55 located at four corners of the lower surface 50b of the light-transmissive member 50 are not completely covered with the bonding member 40. This is because the corner portions 55 of the lower surface 50b of the light-transmissive member 50 are distant from the outer edges of the light-emitting element 20, and thus the uncured bonding member 40 is less likely to spread.

### Step of Disposing First Covering Member

Next, as illustrated in FIG. 3H, the first covering member 61 is disposed on the wiring substrate 10. The first covering member 61 is disposed to cover at least a portion of the bonding member 40. Specifically, first, an uncured first covering member 61 is disposed on the wiring substrate 10. The uncured first covering member 61 can be disposed on the wiring substrate 10 by, for example, potting or spraying. The first covering member 61 covers, for example, the lower surface 20b of the light-emitting element 20, at least a portion of the lateral surfaces 40c of the bonding member 40, the lower surface of the protective element 30, and at least a portion of the lateral surfaces of the protective element 30. Thereafter, the uncured first covering member 61 is cured.

### Removing Step

Next, as illustrated in FIG. 3I, the bonding member 40 covering the lateral surfaces 50c of the light-transmissive member 50, and the lateral surfaces 50c of the light-transmissive member 50 covered with the bonding member 40 are scraped to remove a portion of the bonding member 40 and a portion of the light-transmissive member 50. To be more specific, a rotary blade 350 having a predetermined thickness is moved in the X direction and the Y direction while being rotated to grind the outer periphery of the four lateral surfaces 50c of the light-transmissive member 50 covered with the bonding member 40, thereby processing the light-transmissive member 50 and the bonding member 40 into a predetermined shape. The removal may be performed using a laser, a cutter, or the like.

In the removing step, the bonding member 40 and the light-transmissive member 50 are removed using the alignment mark 300 illustrated in FIG. 3C. For example, when the rotary blade 350 is moved, the rotary blade 350 is positioned with reference to the alignment mark 300, so that the bonding member 40 and the light-transmissive member 50 can be accurately processed into a desired shape. In addition, the positional accuracy of the light-transmissive member 50 relative to the light-emitting element 20 can be improved.

FIG. 3J illustrates a state after the lateral surfaces of the light-transmissive member 50 covered with the bonding member 40 is removed. As illustrated in FIG. 3J, the lateral surfaces 50c of the light-transmissive member 50 exposed from the bonding member are formed by the removing step. The areas of the upper surface 50a and the lower surface 50b of the light-transmissive member 50 after the removing step are smaller than those before the removing step. In the removing step, a lateral surface 50c of the light-transmissive member 50 and a lateral surface 40c of the bonding member 40 are at least partially flush with each other. Further, in the removing step, a portion of the first covering member 61 may be removed together with the bonding member 40 and the light-transmissive member 50. In this case, for example, a lateral surface 50c of the light-transmissive member 50, a lateral surface 40c of the bonding member 40, and a lateral surface 61c of the first covering member 61 are at least partially flush with each other.

When a portion of the bonding member 40 and a portion of the light-transmissive member 50 are removed, the rotary blade 350 may reach a surface of the wiring substrate 10. In this case, the entire lateral surface 61c of the first covering member 61 may be flush with the lateral surface 50c of the light-transmissive member 50 and the lateral surface 40c of the bonding member 40. The first covering member 61 covering the lower surface 20b of the light-emitting element 20 may be separated from the first covering member 61 covering the lower surface and the like of the protective element 30.

As illustrated in FIG. 3K, after the removing step, the entirety of a portion of the lower surface 50b of the light-transmissive member 50 exposed from the light-emitting element 20 is covered with the bonding member 40. That is, even in the case in which the corner portions 55 located at the four corners are not completely covered with the bonding member 40 as illustrated in FIG. 3G, the uncovered portions can still be removed, so that the entire lower surface 50b of the light-transmissive member 50 can be covered with the bonding member 40. This allows light emitted from the light-emitting element 20 to be easily guided to the light-transmissive member 50, so that the light extraction efficiency of the light-emitting device 1 can be improved.

By performing the step of removing a portion of the bonding member 40 and a portion of the light-transmissive member 50 after the step of disposing the first covering member 61, removal can be performed while the light-emitting element 20 is firmly fixed to the wiring substrate 10 by an anchor effect. In addition, it is possible to reduce the adhesion of foreign matter, which is generated when a portion of the bonding member 40 and a portion of the light-transmissive member 50 are removed, to the upper surface of the wiring substrate 10 and the lower surface 20b of the light-emitting element 20.

Step of Disposing Second Covering Member Next, as illustrated in FIG. 3L, the second covering member 62 is disposed to cover the lateral surfaces 50c of the light-transmissive member 50 and the lateral surfaces 40c of the bonding member 40 with the upper surface 50a of the light-transmissive member 50 exposed from the second covering member 62. To be more specific, the uncured second covering member 62 is disposed on the first covering member 61 so as to cover the lateral surfaces 50c of the light-transmissive member 50 and the lateral surfaces 40c of the bonding member 40 and to allow the upper surface 50a of the light-transmissive member 50 to be exposed from the uncured second covering member 62. The uncured second covering member 62 can be disposed on the first covering member 61 by, for example, potting, spraying, or printing. The second covering member 62 may cover the upper surface of the protective element 30 and a portion of the lateral surfaces of the protective element 30. Thereafter, the uncured second covering member 62 is cured to form the covering member 60 made up of the cured first covering member 61 and second covering member 62. Thus, the light-emitting device 1 is obtained.

Before disposing the light-emitting element 20 on the wiring substrate 10, a structure may be produced by disposing the light-transmissive member 50 on the upper surface 20a of the light-emitting element 20 via the bonding member 40, curing the bonding member 40, and scraping the bonding member 40 and the lateral surfaces 50c of the light-transmissive member 50, and removing a portion of the bonding member 40 and a portion of the light-transmissive member 50. Then, this structure may be disposed on the wiring substrate 10.

As described above, in the method of manufacturing the light-emitting device 1, the bonding member 40 is allowed to creep up along the lateral surfaces 50c of the light-transmissive member 50, the bonding member 40 is cured, and then the bonding member 40 covering the lateral surfaces 50c of the light-transmissive member 50 and the lateral surfaces 50c of the light-transmissive member 50 covered with the bonding member 40 are scraped to remove a portion of the bonding member 40 and a portion of the light-transmissive member 50. Thus, in the light-emitting device 1, the lateral surface 50c of the light-transmissive member 50 can be exposed from the bonding member 40. Further, the widths of the light-transmissive member 50 in the X direction and the Y direction can be substantially the same as the widths of the light-emitting element 20 in the X direction and the Y direction, so that the luminance of the light-emitting device 1 can be improved as described above. In addition, the upper surface 20a of the light-emitting element 20 is not exposed from the light-transmissive member 50. Therefore, unevenness in emission color caused by positional deviation or the like can be reduced at the time of light emission.

### Modified Examples

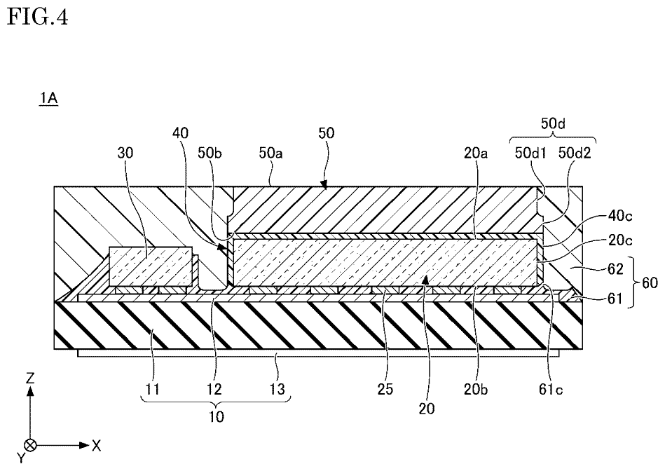

FIG. 4 is a schematic cross-sectional view illustrating a light-emitting device according to Modified Example 1 of the present embodiment. A light-emitting device 1A illustrated in FIG. 4 is different from the light-emitting device 1 in which the light-transmissive member 50 has the lateral surface 50c that does not have a step, in that the light-transmissive member 50 has a lateral surface 50d that is continuous via a step.

In the light-emitting device 1A, each of the lateral surfaces 50d of the light-transmissive member 50 includes a first lateral surface 50d1 connected with the upper surface 50a of the light-transmissive member 50, and a second lateral surface 50d2 located on the outer side relative to the first lateral surface 50d1 and connected with the lower surface 50b of the light-transmissive member 50. The second lateral surfaces 50d2 may be in a frame shape surrounding the outside of the first lateral surfaces 50d1 in a top view.

A portion of the first lateral surface 50d1 at a side connected to the second lateral surface 50d2 may have a recessed curved shape, a linear shape inclined with respect to the upper surface 50a, or a linear shape parallel to the upper surface 50a in a cross-sectional view. In a cross-sectional view, the second lateral surface 50d2 may have a linear shape perpendicular to the upper surface 50a. The second lateral surface 50d2 and the lateral surface 40c of the bonding member 40 are, for example, flush with each other.

In the light-emitting device 1A, the area of the upper surface 50a of the light-transmissive member 50, which serves as the main light-emitting surface, is smaller than that in the light-emitting device 1. Therefore, in the light-emitting device 1A, the luminance can be further improved as compared with the light-emitting device 1. In addition, an anchor effect is exhibited between the lateral surface 50d of the light-transmissive member 50 having a step and the second covering member 62 in contact with the lateral surface 50d, so that the adhesion between the light-transmissive member 50 and the second covering member 62 can be improved.

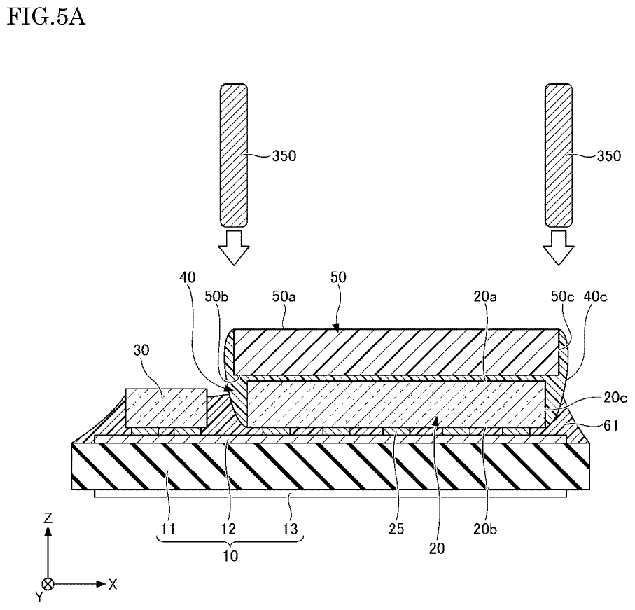

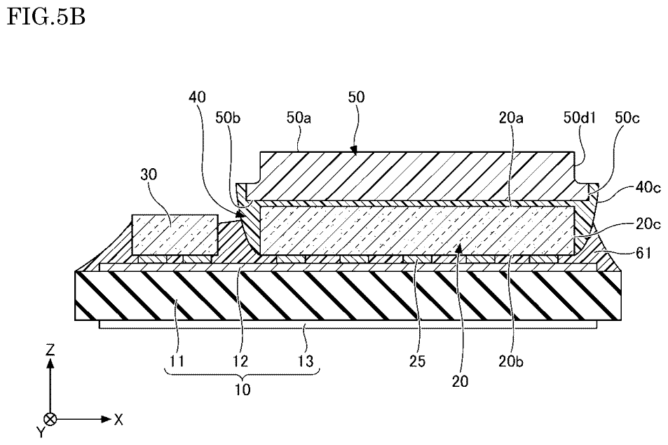

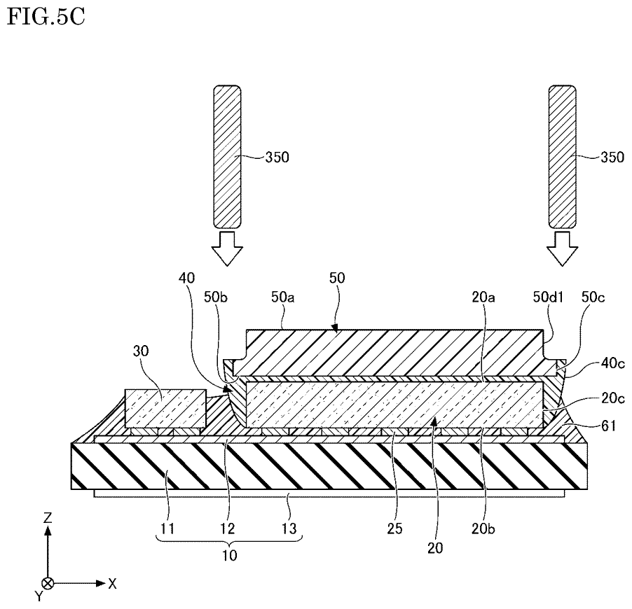

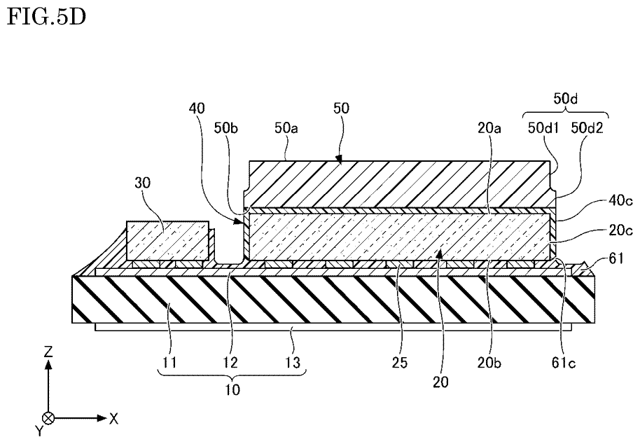

Hereinafter, each manufacturing process of the method of manufacturing the light-emitting device according to Modified Example 1 of the embodiment will be described with reference to the drawings. FIGS. 5A to 5D are diagrams schematically illustrating a manufacturing process of the light-emitting device according to Modified Example 1 of the present embodiment. To be more specific, FIGS. 5A to 5D are cross-sectional views schematically illustrating an example of the manufacturing process of the light-emitting device according to Modified Example 1 of the present embodiment.

In the method of manufacturing the light-emitting device 1A, the step of preparing a light-emitting element, the step of preparing a wiring substrate, the step of disposing the light-emitting element, the step of disposing a bonding member, the step of curing the bonding member, and the step of disposing a first covering member are performed as steps that are the same as or similar to those in FIGS. 3A to 3H, and thereafter, as illustrated in FIGS. 5A to 5D, the step of processing the light-transmissive member 50 is performed so that the area of the upper surface 50a of the light-transmissive member 50 is smaller than the area of the lower surface 50b.

In the step of processing the light-transmissive member 50, first, as illustrated in FIGS. 5A and 5B, the upper side of the lateral surface 50c of the light-transmissive member 50 is removed with the rotary blade 350 having a predetermined thickness to form the first lateral surface 50d1 connected with the upper surface 50a of the light-transmissive member 50. However, the position of the rotary blade 350 in the Z direction is controlled so that the tip of the rotary blade 350 does not reach the lower surface 50b of the light-transmissive member 50. The processing may be performed using a grindstone or the like. In this step, the removal of the light-transmissive member 50 may be performed using the alignment mark 300 illustrated in FIG. 3C.

Subsequently, as illustrated in FIGS. 5C and 5D, the lower side of the lateral surface 50c of the light-transmissive member 50 is removed to form the second lateral surface 50d2 that is located on the outer side relative to the first lateral surface 50d1 in a top view and is connected with the lower surface 50b of the light-transmissive member 50. When the lower side of the lateral surface 50c of the light-transmissive member 50 is removed, a portion of the bonding member 40 covering the lateral surface 50c is also removed, so that the second lateral surface 50d2 is flush with the lateral surface 40c of the bonding member 40. The method of processing the light-transmissive member 50 is the same as or similar to that in the case of FIGS. 5A and 5B. The rotary blade 350 may reach a surface of the wiring substrate 10 when removing the lower side of the lateral surface 50c of the light-transmissive member 50. Thereafter, as illustrated in FIG. 3L, a step of disposing a second covering member is performed to complete the light-emitting device 1A.

In the method of manufacturing the light-emitting device 1A, the step of preparing a light-emitting element, the step of preparing a wiring substrate, the step of disposing the light-emitting element, the step of disposing a bonding member, the step of curing the bonding member, the step of disposing a first covering member, and the removing step, which are illustrated in FIGS. 3A to 3J, may be performed, and then the step of removing an upper side of the lateral surface of the light-transmissive member illustrated in FIGS. 5A and 5B may be performed. In this case, by performing the step of removing the upper side of the lateral surface of the light-transmissive member, the same structure as that illustrated in FIG. 5D, which is obtained by the above-described step of removing the lower side of the lateral surface of the light-transmissive member, is produced, and then, by performing the step of disposing a second covering member illustrated in FIG. 3L, the light-emitting device 1A is completed.

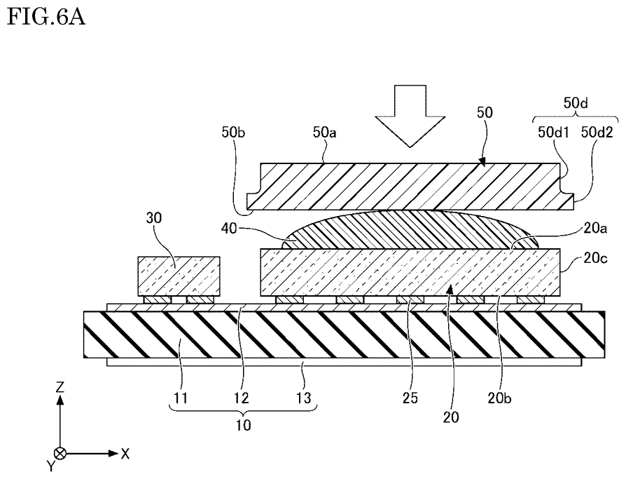

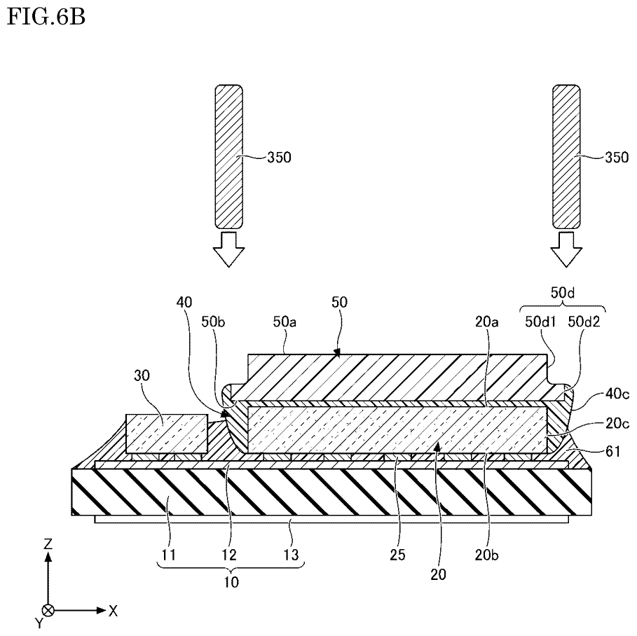

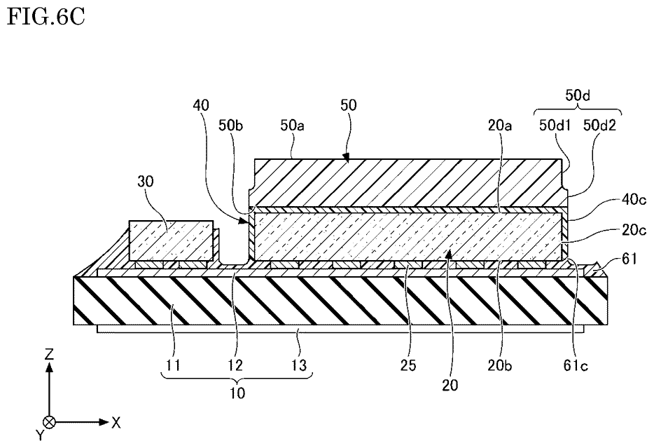

The light-emitting device 1A may be manufactured by the following manufacturing method. FIGS. 6A to 6C are diagrams schematically illustrating another example of the manufacturing process of the light-emitting device according to Modified Example 1 of the present embodiment. To be more specific, FIGS. 6A to 6C are cross-sectional views schematically illustrating another example of the manufacturing process of the light-emitting device according to Modified Example 1 of the present embodiment.

First, the step of preparing a light-emitting element, the step of preparing a wiring substrate, the step of disposing the light-emitting element, and the step of disposing a bonding member are performed as in FIGS. 3A to 3D, and thereafter, as illustrated in FIG. 6A, the light-transmissive member 50 whose lateral surface has been processed to have a step is prepared, and the light-transmissive member 50 is disposed on the upper surface 20a of the light-emitting element 20 via the uncured bonding member 40. The lateral surface 50d of the light-transmissive member 50 to be prepared includes the first lateral surface 50d1 connected with the upper surface 50a of the light-transmissive member 50, and the second lateral surface 50d2 located on the outer side relative to the first lateral surface 50d1 and connected with the lower surface 50b of the light-transmissive member 50. The light-transmissive member 50 to be prepared has a larger area of the lower surface 50b and an equal area of the upper surface 50a as compared to those of the light-transmissive member 50 to be mounted on the light-emitting device 1A.

Subsequently, the step of curing the bonding member and the step of disposing the first covering member are performed as in FIGS. 3F and 3H, and thereafter, as illustrated in FIGS. 6B and 6C, the bonding member 40 covering the second lateral surface 50d2 of the light-transmissive member 50 and the second lateral surface 50d2 of the light-transmissive member 50 covered with the bonding member 40 are scraped with the rotary blade 350 having a predetermined thickness to remove a portion of the bonding member 40 and a portion of the light-transmissive member 50. The processing may be performed using a laser, a cutter, or the like. In this step, the bonding member 40 and the light-transmissive member 50 may be removed using the alignment mark 300 illustrated in FIG. 3C.

In FIG. 6C, the area of the lower surface 50b of the light-transmissive member 50 after the step of removing the lower side of the lateral surface of the light-transmissive member is smaller than the area of the lower surface 50b of the prepared light-transmissive member 50 in FIGS. 6A and 6B. Further, the second lateral surface 50d2 and the lateral surface 40c of the bonding member 40 are flush with each other. Thereafter, as illustrated in FIG. 3L, the step of disposing a second covering member is performed to complete the light-emitting device 1A.

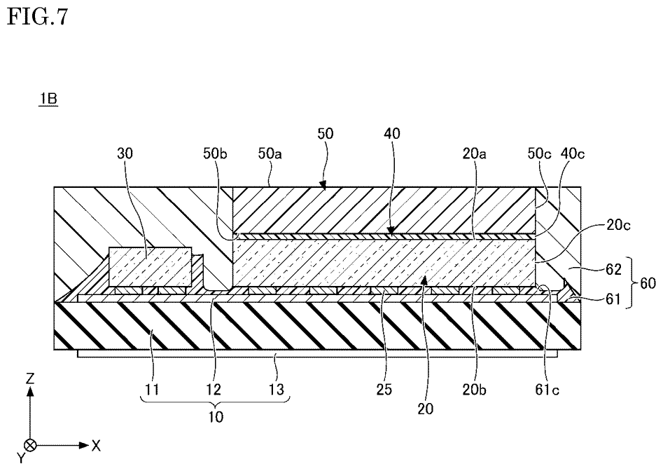

FIG. 7 is a schematic cross-sectional view illustrating a light-emitting device according to Modified Example 2 of the present embodiment. A light-emitting device 1B illustrated in FIG. 7 is different from the light-emitting device 1 in which the bonding member 40 covers the lateral surfaces 20c of the light-emitting element 20 in that the bonding member 40 does not cover the lateral surfaces 20c of the light-emitting element 20.

In the light-emitting device 1B, the bonding member 40 is disposed between the upper surface 20a of the light-emitting element 20 and the lower surface 50b of the light-transmissive member. The bonding member 40 is not disposed on the lateral surfaces 20c of the light-emitting element 20 or the lateral surfaces 50c of the light-transmissive member. In the illustrated example, the lateral surfaces 20c of the light-emitting element 20 and the lateral surfaces 50c of the light-transmissive member are covered with the second covering member 62. The lower end side of the lateral surface 20c of the light-emitting element 20 may be covered with the first covering member 61. The lateral surface 50c of the light-transmissive member 50 is flush with the lateral surface 20c of the light-emitting element 20. The lateral surface 50c of the light-transmissive member 50, the lateral surface 20c of the light-emitting element 20, and the lateral surface 40c of the bonding member 40 may be flush with each other.

In the light-emitting device 1i, the widths of the lower surface 50b of the light-transmissive member 50 in the X direction and the Y direction are substantially the same as the widths of the upper surface 20a of the light-emitting element 20 in the X direction and the Y direction, so that a larger amount of light emitted from the light-emitting element 20 can be easily incident on the light-transmissive member 50. In the light-emitting device 1, the area of the upper surface 50a of the light-transmissive member 50 serving as the main light-emitting surface is even smaller than that in the light-emitting device 1. Accordingly, in the light-emitting device 1, the luminance can be further improved as compared with the light-emitting device 1.

To manufacture the light-emitting device 1, a step of preparing a light-emitting element, a step of preparing the wiring substrate, a step of disposing the light-emitting element, a step of disposing the bonding member, a step of curing the bonding member, and a step of disposing the first covering member are performed as steps that are the same as or similar to those in FIGS. 3A to 3H, and then a removing step is performed as a step that is the same as or similar to that in FIG. 3I. However, unlike the case of manufacturing the light-emitting device 1, in the removing step, the bonding member 40 covering the lateral surface 50c of the light-transmissive member 50, the lateral surface 50c of the light-transmissive member 50 covered with the bonding member 40, and the bonding member 40 covering the lateral surface 20c of the light-emitting element 20 are scraped. Thereafter, the step of disposing a second covering member illustrated in FIG. 3L is performed to complete the light-emitting device 1B.

Certain embodiments and the like have been described in detail above. However, the disclosure is not limited to the above-described embodiments and the like, and various modifications and substitutions can be made to the above-described embodiments and the like without departing from the scope of the claims.

What is claimed is:

1. A method of manufacturing a light-emitting device, the method comprising:
preparing a light-emitting element;
disposing a bonding member on an upper surface of the light-emitting element, the bonding member being uncured;
disposing a light-transmissive member on an upper surface of the light-emitting element via the bonding member, and pressing the bonding member with the light-transmissive member to cause the bonding member to creep up along a lateral surface of the light-transmissive member;
curing the bonding member; and
removing a portion of the bonding member and a portion of the light-transmissive member, which comprises scraping the bonding member covering the lateral surface of the light-transmissive member, and the lateral surface of the light-transmissive member covered with the bonding member.

2. The method of manufacturing a light-emitting device according to claim 1, comprising:
before the step of removing, disposing a first covering member that covers at least a portion of the bonding member.

3. The method of manufacturing a light-emitting device according to claim 2, wherein:
in the step of removing, a portion of the first covering member is removed together with the bonding member and the light-transmissive member.

4. The method of manufacturing a light-emitting device according to claim 2, comprising:
after the step of removing, disposing a second covering member that covers the lateral surface of the light-transmissive member and a lateral surface of the bonding member, wherein an upper surface of the light-transmissive member is exposed from the second covering member.

5. The method of manufacturing a light-emitting device according to claim 1, wherein:
the step of removing comprises processing the light-transmissive member such that an area of an upper surface of the light-transmissive member is smaller than an area of a lower surface of the light-transmissive member.

6. The method of manufacturing a light-emitting device according to claim 5, wherein:
the step of processing the light-transmissive member comprises:
removing an upper side of the lateral surface of the light-transmissive member to form a first lateral surface connected with the upper surface of the light-transmissive member, and
removing a lower side of the lateral surface of the light-transmissive member to form a second lateral surface located on an outer side relative to the first lateral surface in a top view and connected with the lower surface of the light-transmissive member.

7. The method of manufacturing a light-emitting device according to claim 1, comprising, before the step of disposing the bonding member:
preparing a wiring substrate comprising an alignment mark to be used for alignment of the light-emitting element; and
disposing the light-emitting element on the wiring substrate.

8. The method of manufacturing a light-emitting device according to claim 7, wherein:
the bonding member is disposed apart from the wiring substrate.

9. The method of manufacturing a light-emitting device according to claim 7, wherein:
in the step of removing, the bonding member and the light-transmissive member are removed using the alignment mark.

10. A light-emitting device comprising:
a light-emitting element;
a bonding member covering at least a portion of a lateral surface and an upper surface of the light-emitting element;
a light-transmissive member disposed on the upper surface of the light-emitting element via the bonding member;
a first covering member covering a lower surface of the light-emitting element, the first covering member being in contact with the bonding member; and
a second covering member covering a lateral surface of the light-transmissive member and a lateral surface of the bonding member such that an upper surface of the light-transmissive member is exposed from the second covering member, the second covering member being in contact with the first covering member, wherein:
the lateral surface of the light-transmissive member and the lateral surface of the bonding member are at least partially flush with each other.

11. The light-emitting device according to claim 10, wherein:
the lateral surface of the light-transmissive member, the lateral surface of the bonding member, and a lateral surface of the first covering member are at least partially flush with each other.

12. The light-emitting device according to claim 10, wherein:
the lateral surface of the light-transmissive member comprises:
a first lateral surface connected with the upper surface of the light-transmissive member, and
a second lateral surface located outward of the first lateral surface and connected with a lower surface of the light-transmissive member, and
the second lateral surface and the lateral surface of the bonding member are flush with each other.
